(19) United States
(12) Patent Application Publication
(10) Pub. No.: US 2013/0134565 A1
(43) Pub. Date: May 30, 2013

(54) SYSTEM-IN-PACKAGE MODULE AND METHOD OF FABRICATING THE SAME

(71) Applicants: Chi-Sheng Chen, Taipei City (TW); Ching-Feng Hsieh, Taipei (TW)

(72) Inventors: Chi-Sheng Chen, Taipei City (TW); Ching-Feng Hsieh, Taipei (TW)

(73) Assignees: ASKEY COMPUTER CORPORATION, New Taipei City (TW); ASKEY TECHNOLOGY (JIANGSU) LTD., Wujiang (CN)

(21) Appl. No.: 13/367,712

(22) Filed: Feb. 7, 2012

(30) Foreign Application Priority Data
Nov. 25, 2011 (TW) 100143280

(51) Int. Cl. H01L 23/552; H01L 21/56

(52) U.S. Cl. 257/659; 438/127; 257/E23.114; 257/E21.502

(57) ABSTRACT

A method of fabricating a system-in-package (SiP) module is provided, which includes: providing a substrate having a plurality of scribe lines formed thereon, forming ground pads and ground vias along the scribe lines, disposing at least one electronic component on the substrate, forming on the substrate an encapsulant for encapsulating the electronic component, cutting the substrate along the scribe lines so as to expose the ground vias, and forming a shielding layer on the encapsulant and the ground vias to thereby obtain a plurality of SiP modules. Therefore, electromagnetic radiation interferences are avoided and the design complexity and fabrication cost are reduced.

### BACKGROUND OF THE INVENTION

1. Field of the Invention

The present invention relates to package module technologies, and, more particularly, to a system-in-package (SiP) module and a method of fabricating the same.

2. Description of Related Art

Electromagnetic compatibility (EMC) is an important research subject in the electromagnetic field, and how to prevent electromagnetic interferences is an important issue in the fabrication of package modules.

Conventionally, after a package module is produced, a shielding lid is mounted to an outer periphery of the package module for protecting the package module against electromagnetic radiation interferences. However, the shielding lid occupies too much the space in the package module, leaving less space for patterning of circuits.

In fabricating a system-in-package (SiP) module, a molding process is employed by certain manufacturers so as for the package module to have the same appearance as an integrated circuit (IC). But after the molding process, the shielding lid cannot be mounted to the package module. Therefore, the package module cannot be protected against electromagnetic radiation interferences.

Accordingly, in a system having the completed package module, a recess is formed corresponding in position to the package module for protecting the package module against electromagnetic radiation interferences.

However, such a system requires additional components, thereby increasing the design complexity and the fabrication cost. In addition, since the recess corresponds in position to the package module, the positions of the recess and the package module are limited by each other, thus reducing the design flexibility.

Therefore, there is a need to provide a SiP module and a method of fabricating the same so as to overcome the above-described drawbacks.

### SUMMARY OF THE INVENTION

In view of the above-described drawbacks, an object of the present invention is to provide a SiP module and a method of fabricating the same so as to protect the package module against electromagnetic radiation interferences.

Another object of the present invention is to provide a SiP module and a method of fabricating the same so as to reduce the space consumption, the design complexity and the fabrication cost and increase the design flexibility.

In order to achieve the above and other objects, the present invention provides a SiP module, comprising: a substrate having a plurality of scribe lines formed thereon and a plurality of ground vias formed therein along the scribe lines; at least one ground pad formed on the substrate and being adjacent to the ground vias; an electronic component disposed on the substrate; an encapsulant formed on the substrate for encapsulating the electronic component; and a shielding layer formed to cover the encapsulant and the ground vias.

The present invention further provides a method of fabricating a plurality of SiP modules, the method comprising the steps of: (1) providing a substrate having a plurality of scribe lines formed thereon; (2) providing forming at least one ground pad on the substrate along the scribe lines; (3) forming a plurality of ground vias in the substrate within an area enclosed by the at least one ground pad; (4) disposing at least one electronic component on the substrate; (5) forming on the substrate an encapsulant for encapsulating the electronic component; (6) cutting the substrate along the scribe lines so as to expose the ground via; and (7) forming a shielding layer on the encapsulant and the ground vias, thereby obtaining the SiP modules.

According to the present invention, the shielding layer formed on the ground vias is able to ground electromagnetic radiations such that the SiP module is allowed to be protected against electromagnetic radiation interferences. Therefore, the shielding lid of the prior art is replaced by the shielding layer of the present invention. Further, the SiP module of the present invention occupies less space, and has reduced design complexity and fabrication cost and increased design flexibility.

### BRIEF DESCRIPTION OF DRAWINGS

FIG. 1 is a schematic cross-sectional view of a SiP module according to the present invention;

FIG. 2 is a schematic cross-sectional view showing portions of the circuit layers and the dielectric layers of the SiP module of FIG. 1; and

FIGS. 3 to 9 are schematic views illustrating a method of fabricating a plurality of SiP modules according to the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are shown for illustrative purposes only and not intended to limit the present invention.

FIG. 1 is a schematic cross-sectional view of a SiP module 1 according to the present invention. The SiP module 1 has a substrate 11 having a plurality of ground vias 16 penetrating therethrough, an electronic component 12 and a plurality of ground pads 13 disposed on the substrate 11, an encapsulant 15 formed on the substrate 11 for encapsulating the electronic component 12, and a shielding layer 14 formed to cover the encapsulant 15 and the ground vias 16. It should be noted that the SiP module 1 can be applied to various kinds of package modules. In an embodiment, the electronic component 12 is, for example, a semiconductor chip. But it should be noted that the electronic component 12 is not limited to the semiconductor chip. Since the semiconductor chip is well known in the art, further description thereof is omitted.

The substrate 11 has at least one circuit layer 112, a plouality of ground pads 13 formed on the circuit layer 112, and at least one dielectric layer 111 formed on the circuit layer 112 and the ground pads 13. The circuit layer 112 is patterned to form circuits. The ground pads 13 are formed on the circuit layer 112 along scribe lines of the substrate 11. Further, the ground vias 16 are formed along the scribe lines on a top surface 114 of the substrate 11 such that the ground pads 13 are adjacent to the ground vias 16, respectively. The surface area enclosed by each of the ground pads 13 is slightly greater than the surface area enclosed by each of the ground vias 16. In an embodiment, the ground vias 16 are electroplated with metal conductors and electrically connected to the ground pads 13. The dielectric layer 111 separates adjacent circuit layers 112 from each other so as to prevent the circuit layers 112 from being short-circuited.

Two insulating layers 113 are formed on the top surface 114 and the bottom surface 115 of the substrate 11 by a coating process. The insulating layer 113 has a portion formed on the circuit layer 112 and the other portion formed on the dielectric layer 111. In an embodiment, the insulating layer 113 is green paint.

It should be noted that FIG. 1 shows an odd number of circuit layers 112 only for illustrative purposes. In practice, an even number of circuit layers 112 can be provided. Preferably, more than four circuit layers 112 can be provided.

The encapsulant 15 is formed on the substrate 11 for encapsulating all the side and top surfaces of the electronic component 12. The shielding layer 14 is further formed to cover the encapsulant 15 and the ground vias 16. The shielding layer 14 can be a metal layer. The shielding layer 14 can be formed by a sputtering process or a coating process. The shielding layer 14 protects the electronic component 12 against external electromagnetic radiation interferences, i.e., improving the electromagnetic susceptibility (EMS) of the electronic component 12. The shielding layer 14 also prevents the electronic component 12 from generating electromagnetic interferences (EMIs) that adversely affect other systems.

Therefore, through the provision of the shielding layer 14 the SiP module 1 has good electromagnetic compatibility (EMC). It should be noted that the shielding layer 14 can be made of any material having metal properties, such as silver or copper.

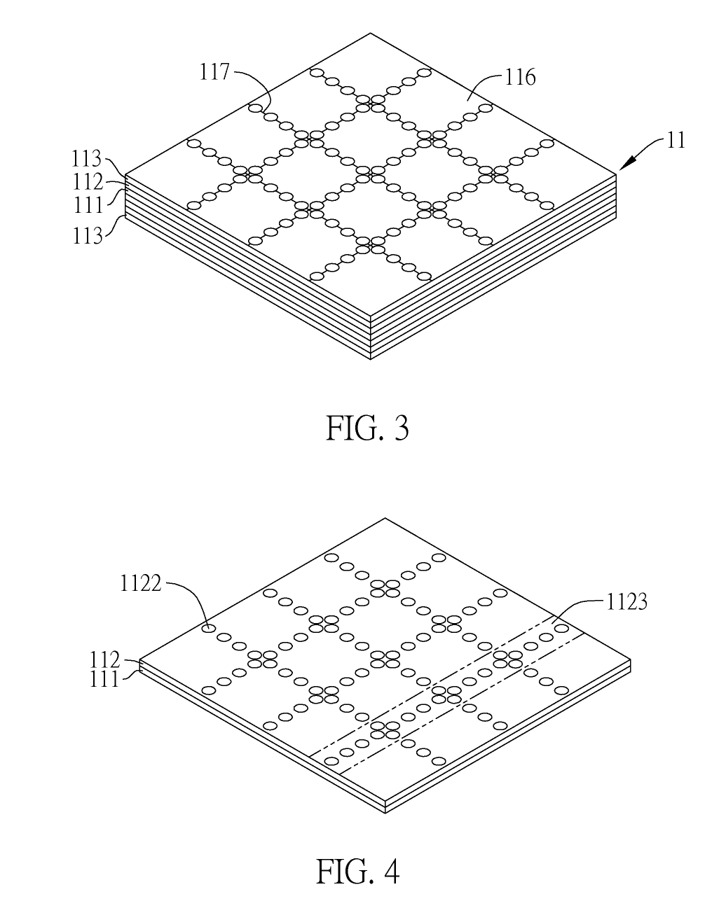

FIGS. 3 to 9 illustrate a method of fabricating a plurality of SiP modules according to the present invention.

Referring to FIG. 3, at step 51 a substrate 11 is provided. The substrate 11 has at least one dielectric layer 111 and at least one circuit layer 112 alternately stacked thereon and an insulating layer 113 formed on the uppermost and lowermost layers. Each of the circuit layers 112 has at least one ground pad 1122. The top surface of the substrate 11 has a plurality of carrying regions 116, and scribe lines 117 are formed between adjacent carrying regions 116. In an embodiment, the insulating layer 113 is green paint. Then, the method proceeds to step S2.

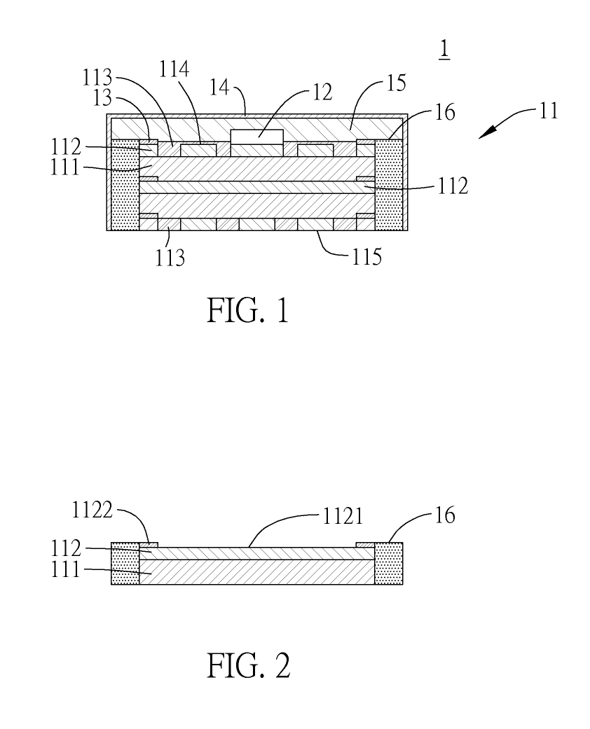

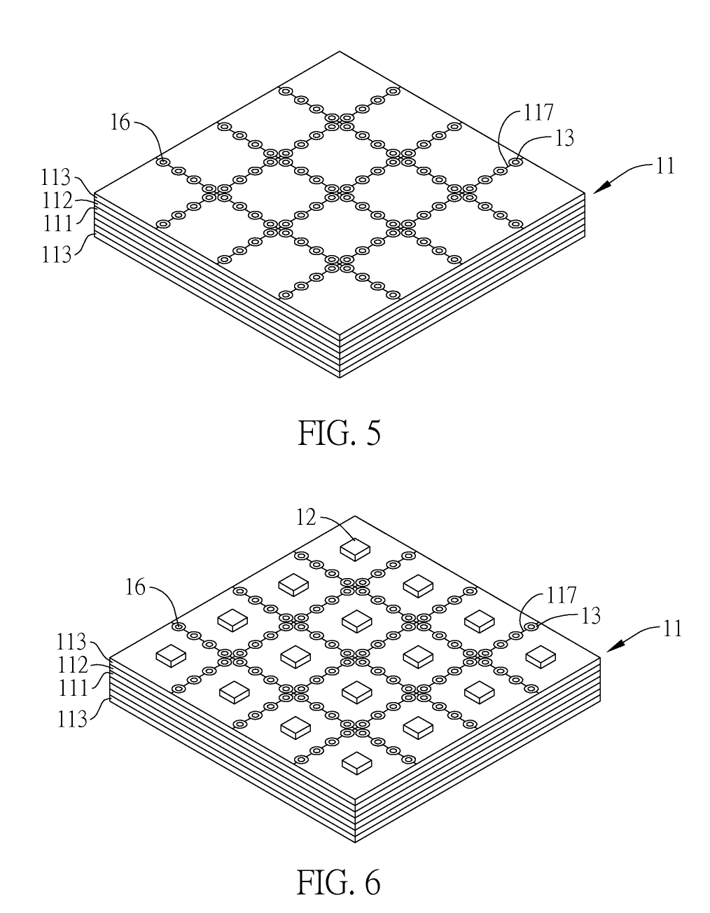

Further refer to FIG. 2 and FIG. 4. FIG. 2 is a schematic cross-sectional view showing portions of the circuit layer 112 and the dielectric layer 111 of the SiP module 1 of FIG.1, and the circuits of the circuit layer 112 are omitted for clarification.

Referring to FIG. 2, the upper surface 1121 of the circuit layer 112 has at least one ground pad 1122 formed in a reserved cutting region. The cutting region is located at a periphery of the upper surface 1121, and the ground pads 1122 are positioned adjacent to the ground vias 16, respectively. The surface area enclosed by each of the ground pads 1122 is slightly greater than the surface area enclosed by each of the ground vias 16.

Accordingly, each of the circuit layers 112 of the substrate 11 has a plurality of ground pads 1122 formed on the upper surface 1121 thereof. The ground pads 1122 of the circuit layers 112 are aligned with each other and adjacent to the conductive vias 16, respectively. Therefore, both the ground pads 13 on the top surface 114 of the substrate 11 and the ground pads 1122 on the upper surfaces 1121 of the circuit layers 112 can be formed adjacent to the conductive vias 16.

Further, since the substrate 11 is formed by alternately stacking the dielectric layer 111 and the circuit layer 112, FIG. 4 only shows the fabrication of a circuit layer 112.

In particular, when the circuit layer 112 is formed, a cutting region 1123 is defined, and at least one ground pad 1122 is disposed in the reserved cutting region 1123.

In practice, the cutting region 1123 is defined during the fabrication of the circuit layer 112 without being marked. In FIG. 4, the cutting region 1123 is specially marked for illustrative purposes.

It should be noted that since the fabrications of the circuit layers 112 are the same, only the fabrication of one circuit layer 112 is exemplified in the present invention. The cutting regions1123 of the circuit layers 112 are located at the same position and the ground pads 1122 of the circuit layers 112 are aligned with each other. The scribe lines 117 correspond in position to the cutting regions 1123 of the circuit layers 112.

Referring to FIG. 5, at step S2 a plurality of grounds pad 13 are formed along the scribe lines 117 on the top surface of the substrate 11. Since the scribe lines 117 correspond in position to the cutting regions 1123, the ground pads 13 are aligned with the ground pads 1122 of the circuit layers 112, respectively. Then, the method proceeds to step S3.

Referring to FIG. 5, at step S3 a conductive via 16 is formed in the region enclosed by one of the ground pads 13 along the scribe lines 117 so as to penetrate the substrate 11. The conductive vias 16 can be formed by a mechanical drilling process or a laser ablation process. Then, the method proceeds to step S4.

Referring to FIG. 6, at step S4 at least an electronic component 12 is disposed in one of the carrying regions 116 on the top surface of the substrate 11. Then, the method proceeds to step S5.

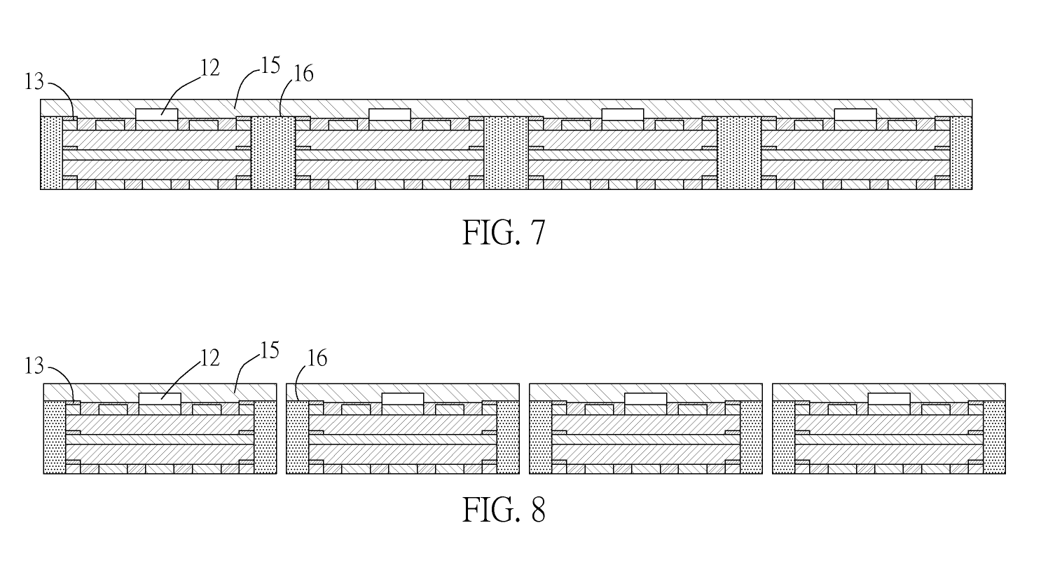

Referring to FIG. 7, at step S5 a molding process is performed such that an encapsulant 15 is formed to encapsulate all the side and top surfaces of the electronic components 12. Then, the method proceeds to step S6.

Referring to FIG. 8, at step S6 a singulation process is performed along the scribe lines 117 so as to separate the substrate 11 into a plurality of substrates each having an electronic component 12 and an encapsulant 15 and ground vias 16 exposed from the encapsulant 15. Then, the method proceeds to step S7.

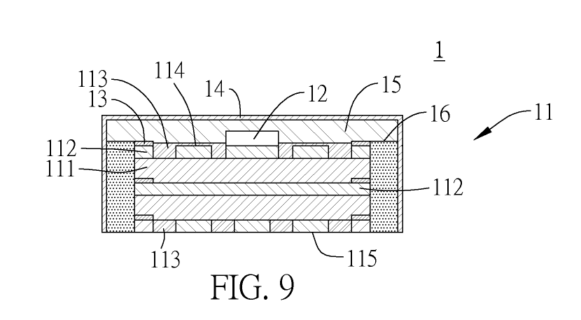

Referring to FIG. 9, at step S7 a shielding layer 14 is formed on the encapsulant 15 and the conductive vias 16 so as to obtain a plurality of SiP modules. In another embodiment, metal conductors are formed in the conductive vias 16 by an electroplating process for electrically connecting the ground pads 13.

The shielding layer 14 is a metal layer and formed by a sputtering process or a coating process. Based on the metal properties of the shielding layer 14, electromagnetic radiation is grounded without adversely affecting the SiP module.

Therefore, the present invention protects the electronic components against electromagnetic radiation interferences. Further, the SiP module of the present invention occupies less space, and has reduced design complexity and fabrication cost and increased design flexibility.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A system-in-package module, comprising:
a substrate having a plurality of scribe lines formed thereon and a plurality of ground vias formed therein along the scribe lines;
at least one ground pad formed on the substrate and being adjacent to the ground vias;
an electronic component disposed on the substrate;
an encapsulant formed on the substrate for encapsulating the electronic component; and
a shielding layer covering the encapsulant and the ground vias.

2. The system-in-package module of claim 1, wherein the at least one ground pad encloses a first surface area greater than a second surface area enclosed by each of the ground vias.

3. The system-in-package module of claim 1, wherein the substrate comprises at least one circuit layer, on which the at least one ground pad is formed, and at least one dielectric layer formed on the at least one circuit layer and the at least one ground pad.

4. The system-in-package module of claim 3, further comprising two insulating layers formed on top and bottom surfaces of the substrate, respectively.

5. The system-in-package module of claim 1, further comprising a metal conductor disposed in at least one of the ground vias.

6. The system-in-package module of claim 1, wherein the shielding layer is a metal layer.

7. The system-in-package module of claim 1, wherein the shielding layer is formed by a sputtering process or a coating process.

8. A method of fabricating a plurality of system-in-package (SiP) modules, comprising the following steps of:
(1) providing a substrate having a plurality of scribe lines formed thereon;
(2) forming at least one ground pad on the substrate along the scribe lines;
(3) forming a plurality of ground vias within an area enclosed by the at least one ground pad;
(4) disposing at least one electronic component on the substrate;
(5) forming on the substrate an encapsulant for encapsulating the electronic component;
(6) cutting the substrate along the scribe lines so as to expose the ground vias; and
(7) forming a shielding layer on the encapsulant and the ground vias, thereby obtaining the SiP modules.

9. The method of claim 8, wherein the substrate comprises at least one circuit layer, on which the at least one ground pad is formed, and at least one dielectric layer formed on the circuit layer and the at least one ground pad.

10. The method of claim 9, wherein two insulating layers are further formed on top and bottom surfaces of the substrate, respectively.

11. The method of claim 8, wherein the ground vias are formed by a mechanical drilling process or a laser ablation process.

12. The method of claim 8, wherein the shielding layer is formed by a sputtering process or a coating process.

13. The method of claim 8, wherein the ground vias are each electroplated with a metal conductor.
